(19) United States
(12) Patent Application Publication
(10) Pub. No.: US 2018/0197835 A1
(43) Pub. Date: Jul. 12, 2018

(54) A SURFACE MOUNT DEVICE AND A METHOD OF ATTACHING SUCH A DEVICE

(71) Applicant: Lumileds Holding B.V., Schiphol (NL)

(72) Inventors: Sander Noijen, Aachen (DE); Rene Ubachs, Aachen (DE); Olaf Van Der Sluis, Aachen (DE)

(21) Appl. No.: 15/740,111

(22) PCT Filed: Jun. 28, 2016
(86) PCT No.: PCT/EP2016/064940

§ 371 Date: Dec. 27, 2017

(30) Foreign Application Priority Data
Jul. 2, 2015 (EP) 15174960.3

(51) Int. Cl. H01L 23/00

(52) U.S. Cl. CPC H01L 24/72; H01L 24/32; H01L 24/92; H01L 24/90; H01L 24/83; H01L 24/73

(57) ABSTRACT

A device comprises a surface mount component on a substrate, in which the surface mount component is attached by a set of discrete mechanical coupling parts and by a bonding layer. This enables the mechanical coupling properties and the electrical/thermal properties to be optimized separately.

### FIELD OF THE INVENTION

This invention relates to surface mount devices.

### BACKGROUND OF THE INVENTION

Surface mounted devices are connected to printed circuit boards by solder interconnects or adhesive materials. These materials serve an electrical, a thermal and a mechanical purpose. In both die-attach methods as well as component-attach methods, the materials used are selected to fulfill stringent electrical and thermal requirements. Once these requirements are met for specific materials, the mechanical reliability of the interconnect is optimized.

This optimization is a challenging task for both adhesive materials and for solder materials. Most adhesive materials have a low stiffness and are mechanically compliant, but can only withstand a limited thermal load due to their low thermal conductivity. Most solder materials have higher moduli, but suffer from low cycle fatigue when operating at typical usage temperatures.

This shows that there is a trade-off between the electrical, thermal and mechanical design of the interconnect. This trade-off hampers the individual optimization of electrical, thermal and mechanical functions.

### SUMMARY OF THE INVENTION

The invention is defined by the claims.

According to examples in accordance with an aspect of the invention, there is provided a device comprising:

a surface mount component; and

a substrate,

wherein the surface mount component is attached to the substrate by a set of discrete mechanical coupling parts and by a bonding layer.

The mechanical coupling parts can separate the mechanical connection function from the electrical and thermal connection functions, which makes it possible to optimize these functions individually. The bonding layer may be designed to provide both electrical and thermal interconnection, or it may specifically be designed for its thermal characteristics. Separate electrical connections may then be provided.

The invention makes it possible to optimize the thermal/electrical properties and the mechanical lifetime separately, exploiting the specific benefits of individual materials, and no longer requiring the trade-off between function and reliability.

The mechanical coupling parts may for example comprise planar interconnection pieces, such as a bar (or strut or sprit), or arrangement of bars, or a sheet structure lying within the plane.

The bonding layer may comprise a single connecting region or it may have separate isolated portions. The bonding layer may for example be an electrically and thermally conductive adhesive layer. It may then perform both electrical and thermal functionality. The boding layer may instead comprise one or more solder connections. There may be an additional layer, for example solder connections forming a first bonding layer designed primarily for the electrical connection properties and an adhesive layer forming a second bonding layer designed primarily for the thermal coupling properties.

The mechanical part is for example optimized by creating a statically determinate fixation. This means that each degree of freedom of the surface mount device is uniquely constrained. This avoids self-stress on the structure due to e.g. thermal loading.

The mechanical coupling can be made at room temperature. Consequently, the disadvantages of high temperature processing are removed, for example exceeding melting points of materials or high thermal stresses. This makes its process compliant with any substrate, die or component, each of which often has maximum processing temperatures.

The surface mount component for example comprises at least one electrical contact pad at a base surface of the component which is connected to the substrate by a conductive adhesive layer. This base contact means that the connection between the surface mount component and the substrate needs to be electrically conductive (unlike the case for a surface mount component where all connections are made by leads extending laterally away from the main body of the device). The electrical contact pad may for example be a ground contact.

The surface mount component may instead comprise a discrete component with a set of at least two contact terminals which extend to the base surface. There may for example be contact terminals at opposite ends of the device which connect down to the substrate. Alternatively, there may be an array of contact pads at the base of the surface mount component.

In another arrangement, the surface mount component comprises a semiconductor component, wherein the semiconductor die is connected to the substrate by the conductive adhesive layer. This is for a die-attach process. In this case, the base of the surface mount component may not be a contact pad as such, but it may be a semiconductor layer.

In one example, the bonding layer may comprise an adhesive with embedded conducting particles. The use of a solder may then be avoided by removing the requirement for a strong mechanical coupling of the thermal and/or electrical connection. This in turn means that lower temperature processes may be used.

The bonding layer may instead comprise a solder connection or an array of solder connections, but with relaxed mechanical requirements.

The mechanical coupling parts of the invention may thus be used to (partly) replace the mechanical function of a system which additionally uses solder connections, or a system having a conductive adhesive. The arrangement of the invention may thus be combined with a solder or with a conductive adhesive. However, these connections no longer need to be designed to carry the mechanical load.

One or more of the mechanical coupling parts may be embedded in the bonding layer. The bonding layer is for example applied after the mechanical coupling parts have been formed.

The mechanical coupling parts may each comprise one of:

a connecting bar such as a strut or sprit;

a pair of crossed connecting bars;

a pad which defines a leaf spring;

a patterned pad which defines a restricted leaf spring.

The mechanical coupling part designs, their number, orientations and positions are for example selected to provide a statically determinate coupling between the substrate and the surface mount component.

The substrate may comprise:

a semiconductor substrate; or

a printed circuit board; or

a lead frame; or

a flex-foil.

Thus, the invention has wide applicability to surface mount technology generally.

The mechanical coupling parts may be formed as integral components with the substrate or formed directly on the substrate. This may for example be achieved by 3D machining of the substrate to define the mechanical coupling parts in the top surface. Alternatively, the mechanical coupling parts may be 3D printed on the top surface of the substrate, or by 3D printing the complete substrate or part of it.

The mechanical coupling parts do not necessarily play a role in the electrical and thermal interconnection between the component and the substrate.

3D printed parts may instead be attached to the substrate using mechanical couplings, for example mechanical couplings that are themselves integrated with the substrate as part of existing (or future) substrate manufacturing technologies. The coupling parts may instead be manufactured separately for example by molding, die casting, machining or additive manufacturing methods. They could be attached to the substrate by soldering, gluing, (3D) printing of a connecting layer such as a weld, or by through hole connections for example using snap-fit connections.

The surface mount component may also have a snap fit connection to the mechanical coupling parts.

Examples in accordance with another aspect of the invention provide a method of manufacturing a device, comprising:

mounting a surface mount component to a substrate using a set of discrete mechanical coupling parts; and

attaching the surface mount component to the substrate using a bonding layer.

The bonding layer may again comprise a conductive adhesive.

The method may comprise forming the mechanical coupling parts as integral components with the substrate or directly over the substrate. The surface mount component may be fitted to the mechanical coupling parts using a snap fit coupling. The method may instead comprise forming the mechanical coupling parts as integral components of the surface mount component.

### BRIEF DESCRIPTION OF THE DRAWINGS

Examples of the invention will now be described in detail with reference to the accompanying drawings, in which:

FIG. 1 shows a known surface mount device attached to a substrate;

FIG. 2 shows a first example of surface mount device attached to a substrate;

FIG. 3 shows a second example of surface mount device attached to a substrate;

FIG. 4 shows three possible designs of mechanical coupling part

FIG. 5 shows four different coupling arrangements;

FIG. 6 shows a snap fit coupling arrangement; and

FIG. 7 shows a manufacturing method.

### DETAILED DESCRIPTION OF THE EMBODIMENTS

The invention provides a device comprising a surface mount component on a substrate, in which the surface mount component is attached by a set of discrete mechanical coupling parts and by a bonding layer, such as a conductive adhesive layer or a solder layer or solder portions. This enables the mechanical coupling properties and the electrical/thermal properties to be optimized separately.

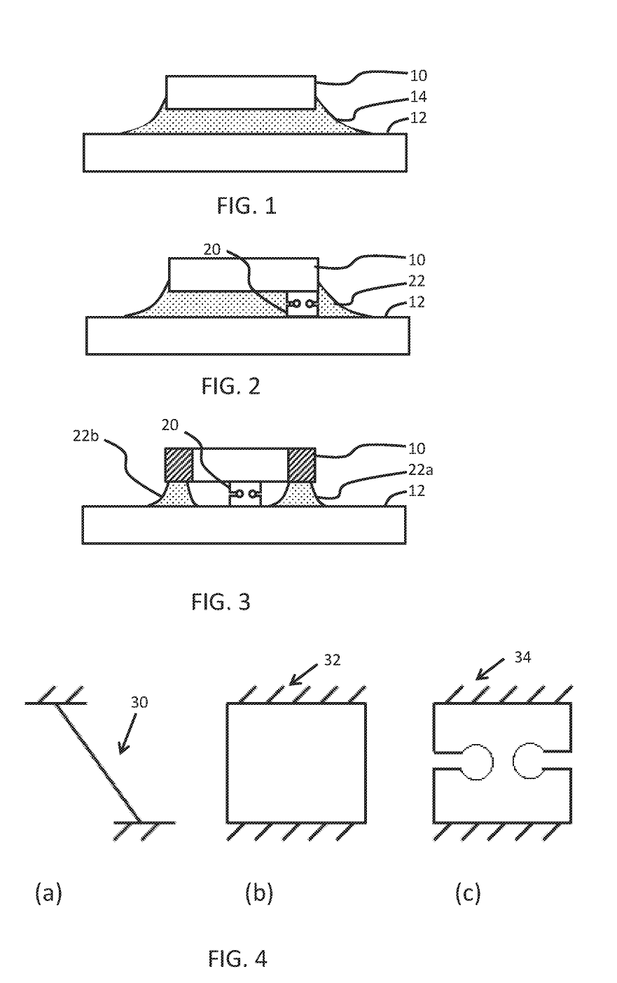

FIG. 1 shows a conventional surface mount device 10 connected to a substrate 12 using a solder or adhesive layer 14 which performs the interconnect function. It has to meet thermal, electrical and mechanical requirements.

FIG. 2 shows an example of the arrangement of the invention. The interconnection function is shared between two parts. A first mechanical coupling part 20 provides a mechanical coupling. A second part 22 is a soft bonding material layer which meets thermal and electrical requirements, but does not need to provide a secure mechanical coupling.

Alternatively, there may be three parts; a mechanical coupling part 20, an electrical connection such as a solder connection or wire connections, which do not need to be designed to provide the full mechanical or thermal support, and an adhesive layer which provides primarily a thermal function.

The invention is of particular interest for a surface mount technology in which an electrically conductive coupling is needed between the main body of the surface mount device and the underlying substrate, i.e. when the base of the surface mount device includes regions to which electrical contact is needed.

This applies to a semiconductor device on a semiconductor die, in which the die needs to be electrically connected to a controlled potential in order to avoid floating potentials. Thus, the electrical connection may not be to a contact pad as such but may be to a semiconductor die (in a die-attach surface mount process).

This also applies to an electrical component (which may be active or passive) with contact terminals at its base. For example, a surface mount capacitor may have terminals at the ends, which extend down to the bottom surface layer.

This also applies to an electronic component with a ground terminal at its base, in addition to other terminals which may for example be provided by contact leads.

This also applies to an electronic component with a set of contact terminals at its base and these may be the only contact terminals to the component.

In some other examples, a component may have the required electrical connection implemented by connecting wires or leads or by solder ball connections such as a ball grid array. In this case, the remaining thermal and mechanical functions may be decoupled by using the mechanical coupling parts and the bonding layer which then does not need to be electrically conductive. The invention is however of particular interest for surface mount devices without leads.

The examples above show that a conductive adhesive layer may be a single layer as shown in FIG. 2, but it may have different portions 22a, 22b as shown in FIG. 3 for electrical connection to different regions of the base of the surface mount component.

The separate portions 22a, 22b may be separate regions of a conductive adhesive layer. Alternatively, the portions 22a, 22b may be solder portions which then define the bonding layer. They then provide thermal as well as electrical coupling. They also provide mechanical coupling but the mechanical properties can be relaxed as a result of the use of the mechanical coupling parts 20.

A separate additional adhesive layer may optionally also be provided in addition to the solder connection and mechanical coupling parts. The additional adhesive layer for example may extend over a larger area than the area of the solder portions.

The connections between the component and the substrate may be considered to be die attach parts which are for thermal and mechanical coupling of the component to the substrate, and component attach parts which are for electrical coupling of the component to the substrate. The mechanical coupling parts function only as a die attach parts and they are designed to provide the required mechanical coupling properties.

The mechanical coupling parts 20 fix the surface mount device 10 to the substrate with a mechanical connection which may have some elasticity. The connection is preferably statically determinate or approximately statically determinate.

A statically determinate structure (otherwise known as “isostatic”) is completely constrained and functions as an exact constraint kinematic coupling. Its structure reduces or eliminates the possibility of self-stress, i.e. stress in the absence of an external load, that may be induced by mechanical or thermal action. Thus, the mechanical coupling is able to minimize the internal load interaction between the component 10 and the substrate 12 and eliminates the possibility of self-stress.

Additionally, the mechanical coupling can be designed to be stressed in the elastic range only. The coupling parts in this way only have reversible elastic deformation so that after release of the present load the mechanical coupling reverts back to its original shape. This reduces or eliminates fatigue in the coupling parts which increases lifetime of the parts and the system.

The stress in the mechanical coupling and also in the component itself may be minimized, which maximizes the lifetime.

The bonding layer may function both as a thermal coupling for the component and an electrical attachment. These two functions may be performed by a single design of bonding layer, such as a thermally conductive adhesive, or as separate parts, such as electrical solder connections combined with a thermally coupling bonding layer.

The electrical and thermal functionality is achieved with standard materials, such as standard high conductivity low stiffness materials. One example is an adhesive which is filled with conductive particles. The mechanical properties of these materials are of secondary importance as the mechanical functionality is fulfilled by the mechanical coupling part 20.

The invention thus relates in particular to the mechanical coupling part 20 which enables the elastic (near) statically determinate fixation of the component 10 to the substrate 12.

The development of additive manufacturing technologies (e.g. 3D printing) enables the fabrication of small detailed elastic components such as leaf springs, restricted leaf springs and sprits or struts (which are referred to generally as connecting bars in the text and claims below).

FIG. 4(a) shows a diagonal connection strut 30 (known as a sprit). Such a strut may be used as a vertical or a horizontal connector as well. FIG. 4(b) shows a leaf spring 32, and FIG. 4(c) shows a restricted leaf spring 34. The restricted leaf spring has a pattern formed in its surface to define channels. These alter the spring characteristics. The channels allow relative rotation of the top and bottom edges of the leaf spring. Note that a pair of crossed struts functions in the same way as a restricted leaf spring.

These structures are each planar (although the crossed struts may have a thicker central part), and they allow some elastic deformation perpendicular to the plane.

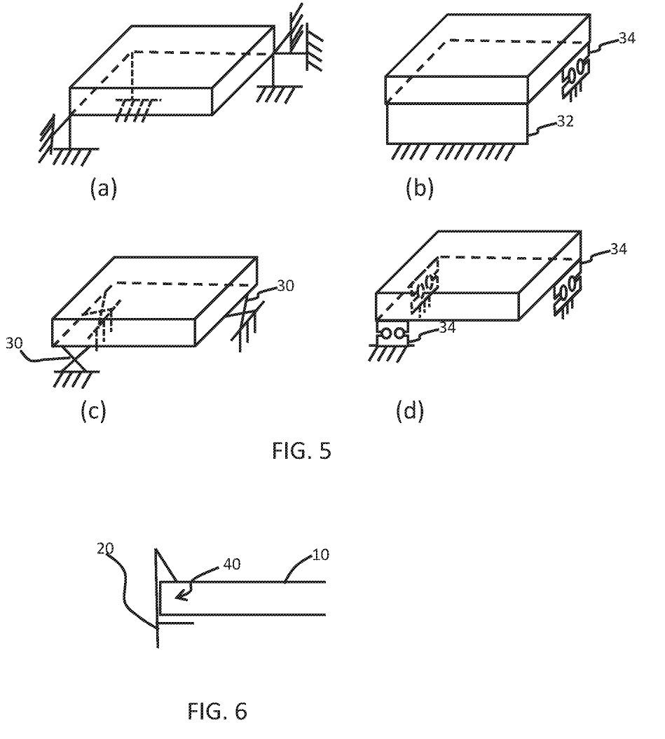

FIG. 5 shows various possible connection schemes to provide a statically determinate structure.

FIG. 5(a) shows a set of three vertical couplings between the two components as well as a set of three lateral couplings. The mechanical coupling parts are all connecting bar couplings.

FIG. 5(b) shows a set of two vertical couplings between the two components in which one comprises a restricted leaf spring 34 and the other comprises a full leaf spring. They are vertical but they are orthogonal to each other. The full leaf spring extends across the full width of one side of the component, so that only two mechanical coupling parts are needed to form the desired statically determinate structure.

FIG. 5(c) shows a set of three vertical couplings between the two components, each in the form of a pair of crossed bars 30.

FIG. 5(d) shows a set of three vertical couplings between the two components, each in the form of a restricted leaf spring 34.

The number of mechanical coupling parts is unrelated to the number of electrical connections between the component and the substrate. There may for example be exactly two or three mechanical coupling parts as shown in the examples above, in which one mechanical coupling part is taken to comprise all of the parts which attach to a particular location of the component. For example, FIG. 5(a) shows three mechanical coupling parts; one at each of three corners of the components. FIG. 5(b) shows two mechanical coupling parts, one along one edge of the component and one at another corner.

The mechanical coupling parts may be conductive or insulating. They connect to regions of the component away from (i.e. excluding) electrical contact terminals, for example insulating regions of the component.

The height of the mechanical coupling parts is designed such that the components are only loaded in the elastic range. As explained above, the mechanical coupling parts can be created for example by 3D printing on the substrate, or 3D machining of the substrate itself, be separate manufacture followed by attachment to the substrate or the component, or by other methods.

The connection between the surface mount component 10 and the mechanical coupling parts 20 can be made by a clamp or clicking system. A possible solution is shown in FIG. 6.

The surface mount component 10 is a snap fit in a retaining channel 40 formed as part of the mechanical coupling part 20.

The invention can be applied to any surface mount device or die that needs to be attached to a substrate, wherein the substrate may be a printed circuit board, a flex-foil, or a lead frame for example.

The mechanical coupling parts may for example be formed using metals such as Aluminum or Copper, but it is also possible to use plastic parts for example if using injection molding or 3D printing.

The mechanical coupling parts may have dimensions of 10-300 μm height and width in the same range, for example identical height and width. Thickness of the parts may be approximately 1-10 μm. Thus, the mechanical coupling parts are planar structures, by which is meant the thickness is at most 1/10 of the largest in-plane dimension, and the shape is generally flat, although not necessarily perfectly planar. In the case of struts as in FIG. 4(a), they are again planar in that the thickness is at most 1/10 of the length (which is the largest in-plane dimension). A strut may be considered to be a 1 dimensional connection and a leaf spring or crossed strut arrangement may be considered to be a 2 dimensional connection.

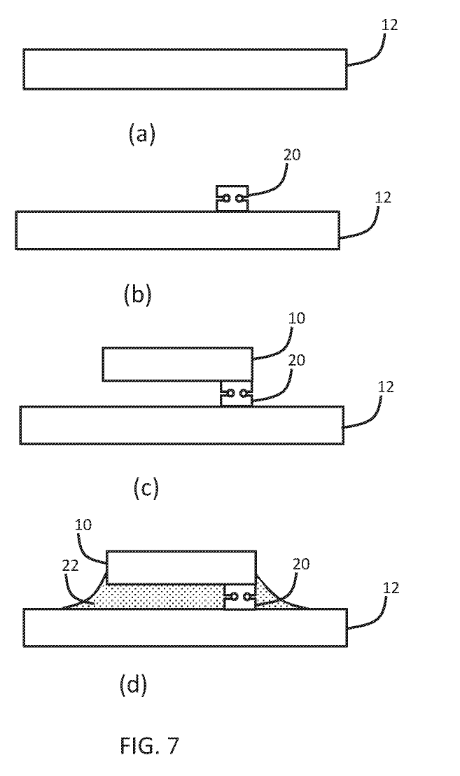

FIG. 7 shows a manufacturing method.

FIG. 7(a) shows a substrate 12, which may be a semiconductor substrate, a printed circuit board, a lead frame or a flex foil.

The mechanical coupling part 20 is formed for example by layer deposition over the substrate, for example by a 3D printing process, to provide the structure shown in FIG. 7(b).

As shown in FIG. 7(c) the surface mount component is attached to the mechanical coupling part 20, for example by a snap fit coupling.

The adhesive layer is then injected as shown in FIG. 7(d). Alternatively, the adhesive layer can be applied before attaching the surface mount component 10, then cured after attaching the surface mount component 10.

Other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measured cannot be used to advantage. Any reference signs in the claims should not be construed as limiting the scope.

1. A device comprising:
a surface mount component; and
a substrate,
wherein the surface mount component is attached to the substrate by a set of discrete mechanical coupling parts and by a bonding layer; and
wherein the mechanical coupling parts provide a statically determinate coupling between the substrate and the surface mount component and are created by 3D printing on the substrate or 3D machining of the substrate; and wherein the bonding layer provides electrical and/or thermal interconnection between the surface mount component and the substrate.

2. A device as claimed in claim 1, wherein the bonding layer is an electrically conductive adhesive layer.

3. A device as claimed in claim 2, wherein the bonding layer comprises an adhesive with embedded conducting particles.

4. A device as claimed in claim 2, wherein the surface mount component comprises at least one electrical contact pad at a base surface of the component which is connected to the substrate by the conductive adhesive layer.

5. A device as claimed in claim 4, wherein the surface mount component comprises a ground contact at its base.

6. A device as claimed in claim 4, wherein the surface mount component comprises a discrete component with a set of at least two contact terminals which extend to the base surface.

7. A device as claimed in claim 1, wherein the surface mount component comprises a semiconductor component, wherein the semiconductor die is connected to the substrate by the bonding layer.

8. A device as claimed in claim 1, wherein one or more of the mechanical coupling parts are embedded in the bonding layer.

9. A device as claimed in claim 1, wherein the mechanical coupling parts each comprise one of:
a connecting bar;
a pair of crossed connecting bars;
a pad which defines a leaf spring;
a patterned pad which defines a restricted leaf spring.

10. A device as claimed in claim 1, wherein the substrate comprises:
a semiconductor substrate; or
a printed circuit board; or
a lead frame; or
a flex foil.

11. A device as claimed in claim 1, wherein the mechanical coupling parts are formed as integral components with the substrate, or formed directly over the substrate and optionally wherein the surface mount component is a snap fit to the mechanical coupling parts.

12. A method of manufacturing a device, comprising:
mounting a surface mount component to a substrate using a set of discrete mechanical coupling parts providing a statically determinate coupling between the substrate and the surface mount component, which mechanical coupling parts are created by 3D printing on the substrate or 3D machining of the substrate; and
after mounting the surface mount component to the substrate providing a bonding layer providing electrical and/or thermal interconnection between the surface mount component and the substrate.

13. A method as claimed in claim 12, wherein providing the bonding layer comprises providing a conductive adhesive layer.

14. A method as claimed in claim 12, comprising forming the mechanical coupling parts as integral components with the substrate, or integral components with the components, or directly over the substrate.
